(19) United States
(12) Patent Application Publication
(10) Pub. No.: US 2011/0087949 A1
(43) Pub. Date: Apr. 14, 2011

(54) RECONFIGURABLE TURBO INTERLEAVERS FOR MULTIPLE STANDARDS

(75) Inventors: Angelo Raffaele Dilonardo, Martina Franca (IT); Nur Engin, Eindhoven (NL)

(73) Assignee: NXP B.V., Eindhoven (NL)

(21) Appl. No.: 12/996,783

(22) PCT Filed: Jun. 6, 2009
(86) PCT No.: PCT/IB2009/052448

§ 371 Date: Dec. 8, 2010

(30) Foreign Application Priority Data
Jun. 9, 2008 (EP) 08104307.7
Jun. 9, 2009 (IB) PCT/IB2009/052448

(51) Int. Cl. H03M 13/45; H03M 13/27; G06F 11/10

(52) U.S. Cl. 714/768; 714/E11.034

(57) ABSTRACT

A data processing system, a turbo decoding system, an address generator and a method of reconfiguring a turbo decoding method is provided. The data processing system (101) comprises the turbo decoding system (100). The turbo decoding system (100) comprises electronic circuits. The electronic circuits comprises: a memory (108), the address generator (102), and a Soft Input Soft Output decoder (106). The address generator (102) is operative to produce a sequence of addresses according to an interleaving scheme. The address generator can support multiple interleaving schemes. The address generator (102) is operative to receive reconfiguration information. The address generator (102) is operative to reconfigure during operational use the interleaving scheme in dependency on the reconfiguration information.

### FIELD OF THE INVENTION

The invention relates to a data processing system comprising a turbo decoding system.

The invention also relates to a turbo decoding system.

The invention also relates to an address generator.

The invention also relates to a method of reconfiguring a turbo decoding method.

### BACKGROUND OF THE INVENTION

Turbo codes are related to channel coding schemes, which are used, e.g., in wireless communication and networking standards, such as: the Universal Mobile Telecommunications System (UMTS), Code division multiple access 2000 (CDMA2000), Worldwide Interoperability for Microwave Access (WiMax), Wireless Broadband (WiBro) the High-Speed Downlink Packet Access (HSDPA) protocol, etc.

For example, a sender encodes original data using a turbo encoder for transmission; a receiver decodes received data using a turbo decoder. During transmission errors may occur. The use of a turbo encoder and turbo decoder allows the correction of some errors.

The throughput requirements of wireless standards have been increasing. New standards, such as UMTS LTE, require over 100 Mbps peak throughput.

A turbo decoder comprises two main parts, a Soft-Input-Soft-Output (SISO) decoder, and an interleaver. During execution, the decoder works on so-called soft data. Soft data gives probabilistic information on the data that was originally sent. The decoder and interleaver cooperate in an iterative process to correct the errors in a received data frame. For example, first the decoder corrects a few errors in the data. Next, the frame is interleaved and decoded again. In this way, in each iteration more errors are corrected.

These iterations are repeated for a predefined number of times or until a pre-defined stopping criterion is satisfied.

The interleaving rules to be used during the decoding are specified in the communication standard.

The structure and operation of turbo decoders is, for example, described in S. A. Barbulescu and S. S. Pietrobon, “Turbo codes: A tutorial on a new class of powerful error correcting coding schemes, Part 1: Code structures and interleaver design”, J. Elec. and Electron. Eng., Australia, vol. 19, pp. 129-142, September 1999; and S. A. Barbulescu and S. S. Pietrobon, “Turbo codes: A tutorial on a new class of powerful error correcting coding schemes, Part 2: Decoder design and performance,” J. Elec. and Electron. Eng., Australia, vol. 19, pp. 143-152, September 1999.

Recently, parallel turbo decoder architectures were introduced. A parallel turbo decoder architecture employs multiple SISO decoders to work in parallel on the same received data frame. With a parallel turbo decoder a conflict-free interleaver is typically used. Conflict-free interleavers are described, for example, in Neeb, C., Thul, M. J. and Wehn, N, 2005, “Network-on-chip-centric approach to interleaving in high throughput channel decoders”, Circuits and Systems, ISCAS 2005, IEEE International Symposium on 23-26 May 2005, page(s):1766-1769 Vol. 2.

### SUMMARY OF THE INVENTION

As turbo decoders are computationally and memory intensive, turbo decoders are mostly implemented in dedicated hardware. If multiple standards need to be supported, then each interleaved address generation block is currently implemented in a dedicated hardware block.

It is a problem of the prior art that existing address generators for interleaving only support a single interleaving scheme.

It is an object of the invention to provide an architecture that can support multiple interleaving schemes.

The object is achieved by the data processing system according to the invention. The data processing system according to the invention comprises a turbo decoding system. The turbo decoding system comprises electronic circuits. The electronic circuits comprise: a memory, an address generator, and a Soft Input Soft Output decoder. The memory is operative to store a first information. The address generator is operative to produce a sequence of addresses according to an interleaving scheme. The memory is operative to retrieve the first information as indicated by the sequence of addresses. The Soft Input Soft Output decoder is operative to produce a second information by performing a turbo decoding half-iteration on the retrieved first information. The memory is operative to store the second information as indicated by the sequence of addresses. The address generator is operative to receive reconfiguration information. The address generator is operative to reconfigure during operational use the interleaving scheme in dependency on the reconfiguration information.

By making the interleaver reconfigurable, the object of supporting multiple interleaving schemes is achieved. For example, the electronic circuits could first be used for one standard, then the interleaver could be reconfigured, and then the electronic circuits can be used for a second standard. In this way, only one hardware block is needed to support two or more standards. This saves on footprint, material cost and complexity.

Conventional multi-standard turbo decoders require a separate interleaver for each supported standard. This results in a large chip area to support the separate address generators. It also increases design time. Moreover, if a new standard needs to be supported, new address generation circuitry needs to be designed from scratch. In a data processing system according to the invention, a new set of reconfiguration data may be uploaded and used to make the hardware support the new interleaving scheme. A costly redesign of the hardware is not necessary, which also reduces the time to market.

The electronic circuits can be implemented in any suitable form, for example, using CMOS technology.

The turbo decoder performs a series of half-iterations. During each half-iteration processing is done on information. The information may be received, first as a signal from an antenna, which signal is then demodulated. The information may also come from some other source, e.g., from storage. The Soft Input Soft Output decoder typically operates on soft data, that is, on log likelihood values of the symbols.

The reconfiguration data may include such items as one or more parameters representative of formulas, one or more parameters turning some special hardware on or off, one or more modulus values for use during computation, one or more start values for algorithms, etc.

In a preferred embodiment of the system according to the invention, the interleaving scheme is based on a polynomial. The address generator comprises a polynomial evaluator. The polynomial evaluator is operative to produce a polynomial evaluation. The polynomial evaluator comprises a first plurality of parameters representative of the polynomial. The reconfiguration information comprises at least one second plurality of parameters representative of a reconfigured polynomial.

An interleaving scheme based on a polynomial involves the evaluation of the polynomial for a sequence of consecutive input values. Interleaving schemes based on polynomials include the important class of linear interleavers. The reconfiguration data may include a list of the coefficients of the polynomials. The evaluation of the polynomial might use straightforward arithmetic to perform multiplications, additions, and raising to a power. In a more advanced implementation, the evaluation of the polynomial might use Horner's rule, as described, e.g., in Knuth, D. E. The Art of Computer Programming, Vol. 2: Seminumerical Algorithms.

In a practical embodiment of the system according to the invention, the polynomial evaluator comprises: a third plurality of adders, a fourth plurality of buffers and a configuration unit. The third plurality of adders is ordered linearly, the third plurality of adders comprises a first adder and a last adder. To each specific one of the third plurality of adders is associated a specific one of the fourth plurality of buffers. Each specific one of the third plurality of adders is configured to produce a specific output by adding, modulo a first number, a specific fifth plurality of inputs. The specific fifth plurality of inputs comprises a contents of the specific buffer associated with the specific adder. The specific adder is configured to store the specific output in the specific buffer. The specific fifth plurality of inputs to each specific one of the third plurality of adders, except the first adder, comprises a contents of a specific previous buffer associated with a specific previous adder. The last adder produces a last output, which last output is representative of the polynomial evaluation. The configuration unit is operative to store in each specific one of the fourth plurality of buffers a specific one of the first plurality of parameters representative of the polynomial or of the second plurality of parameters representative of the reconfigured polynomial.

Using a polynomial evaluator of this kind is particularly efficient as it replaces multiplications with modular additions. In general a modular addition is easier to compute. Accordingly, the polynomial evaluations will be ready more quickly, in turn leading to a higher throughput. Alternatively, the polynomial evaluations need less complex hardware in order to deliver the same throughput as hardware using a less advanced polynomial evaluator.

In a preferred embodiment of the system according to the invention, the address generator comprises a further memory and a counter. The further memory is operative to store a seventh plurality of numbers. The turbo decoding system is operative to increment the counter in conjunction with the Soft Input Soft Output decoder performing the turbo decoding half-iteration. The further memory is operative to retrieve a specific one of the seventh plurality of numbers in dependency on the counter. The last adder is operative to receive as input an eighth plurality of inputs; the eighth plurality of inputs comprises the specific number.

Adding a means to insert a number increases the number of interleaving schemes the electronic circuits can handle. Accordingly, a larger body of standards can be supported.

In a preferred embodiment of the system according to the invention the address generator comprises a further memory and a counter. The further memory is operative to store a seventh plurality of numbers. The turbo decoding system is operative to increment the counter in conjunction with the Soft Input Soft Output decoder performing the turbo decoding half-iteration. The further memory is operative to retrieve a specific one of the seventh plurality of numbers in dependency on the counter. A particular one of the third plurality of adders is configured to receive an input from a particular previous adder and the specific number. The particular adder is operative to select one of the inputs from the particular previous adder and the specific number, for use in the adding.

The flexibility of the polynomial evaluator is further increased by making an input from a further memory selectable. This leads to an even greater number of interleaving schemes that could be used.

In a practical embodiment a data processing system as in any one of the previous claims accommodated in a mobile communication device.

Modern mobile communication devices are a typical example of technological convergence. A modern mobile communication device is expected to support many types of standards. At the same time, a mobile communication device is under pressure to reduce cost and design effort. For these reasons, a data processing system according to the invention is particularly well suited for in use in a mobile communication device.

The turbo decoding system according to the invention is for use in a data processing system according to the invention.

The address generator according to the invention, is for use in a data processing system according to the invention.

The method of reconfiguring a turbo decoding method according to the invention comprises receiving reconfiguration information and reconfiguring during operational use of the turbo decoding method an interleaving scheme in dependency on the reconfiguration information. The turbo decoding method comprising: producing a sequence of addresses according to the interleaving scheme; retrieving a first information from a memory as indicated by the sequence of addresses; producing a second information by performing a turbo decoding half-iteration on the retrieved first information; and storing the second information as indicated by the sequence of addresses.

The computer program product comprises computer code for implementing the method of reconfiguring according to the invention.

### BRIEF DESCRIPTION OF THE DRAWINGS

The invention is explained in further detail by way of example and with reference to the accompanying drawings, wherein:

FIG. 1 is a block diagram showing a first embodiment of a decoding system according to the invention.

FIG. 2 is a block diagram showing an embodiment of an address generator.

FIG. 3 is a block diagram showing an embodiment of turbo decoding system 100.

FIGS. 4 and 5 show various formulas related to interleaving.

FIG. 6 shows a memory mapping of data words in a memory for use with an interleaver.

FIG. 7 shows an embodiment of a polynomial evaluator.

FIGS. 8 and 9 show formulas used to compute parameters for use in a polynomial evaluator.

FIG. 10 shows an embodiment of a polynomial evaluator.

FIG. 11 shows the first few values of the buffers 708, 704 and output 724.

FIG. 12 shows formulas related to parallel use of an interleaver.

FIG. 13 shows a further embodiment of a polynomial evaluator 1300.

FIG. 14 shows a further embodiment of a polynomial evaluator 1400.

FIG. 15 is a flowchart representing a method of reconfiguring a turbo decoding method.

Throughout the Figures, similar or corresponding features are indicated by same reference numerals.

### LIST OF REFERENCE NUMERALS

100 a decoding system
101 a data processing system
102 an address generator
104 a controller
106 a decoder
108 a memory
110 a reconfiguration means
112 a connection for writing to a memory
114 a connection for reading from a memory
200 an interleaved address generator
202 a linear address generator
300 a basic sequence generator
302 a memory bank
304 a memory bank
306 a memory bank
308 a memory bank
310 a network
312 a decoder
314 a decoder
316 a decoder
318 a decoder
401 a formula for calculating the sub-sequence length ‘w’ from ‘k’ and ‘N’
402 an entire interleaver sequence
403 sub-sequences comprised in interleaver sequence 402
404 a polynomial expression specifying a linear interleaver
501 a list of elements that need to be retrieved from memory at moment j, for N=4
502 a list of elements that need to be retrieved from memory at moment j, for N=8
503 a formula giving a relation between a line address and an interleaving address
504 a property of the line address
505 a formula for computing the index
700 a polynomial evaluator
702, 706, 710, 714, 718 adders
704, 708, 712, 716, 720 buffers
722 an input
724 an output
726 a configuration unit
800 a table giving formulas to compute the parameters that are to be placed by the configuration unit 726 in the buffer of polynomial evaluator 700
900 a table
902 recurrence relations
1000 a quadratic permutation polynomial
1002 a polynomial evaluator
1200 a property of a parallel interleaver
1202 the first element of each sub-sequence, when N=4
1204 a table identify the first element of each sub-sequence
1300 a polynomial evaluator
1302 a counter
1304 a further memory
1400 a polynomial evaluator
1402 a multiplexer
1502 receiving reconfiguration information
1504 reconfiguring an interleaving scheme in dependency on the reconfiguration information
1506 producing a sequence of addresses according to the interleaving scheme
1508 retrieving a first information from a memory as indicated by the sequence of addresses
1510 producing a second information by performing a turbo decoding half-iteration on the retrieved first information
1512 storing the second information as indicated by the sequence of addresses.

### DETAILED DESCRIPTION OF THE EMBODIMENTS

While this invention is susceptible of embodiment in many different forms, there is shown in the drawings and will herein be described in detail one or more specific embodiments, with the understanding that the present disclosure is to be considered as exemplary of the principles of the invention and not intended to limit the invention to the specific embodiments shown and described.

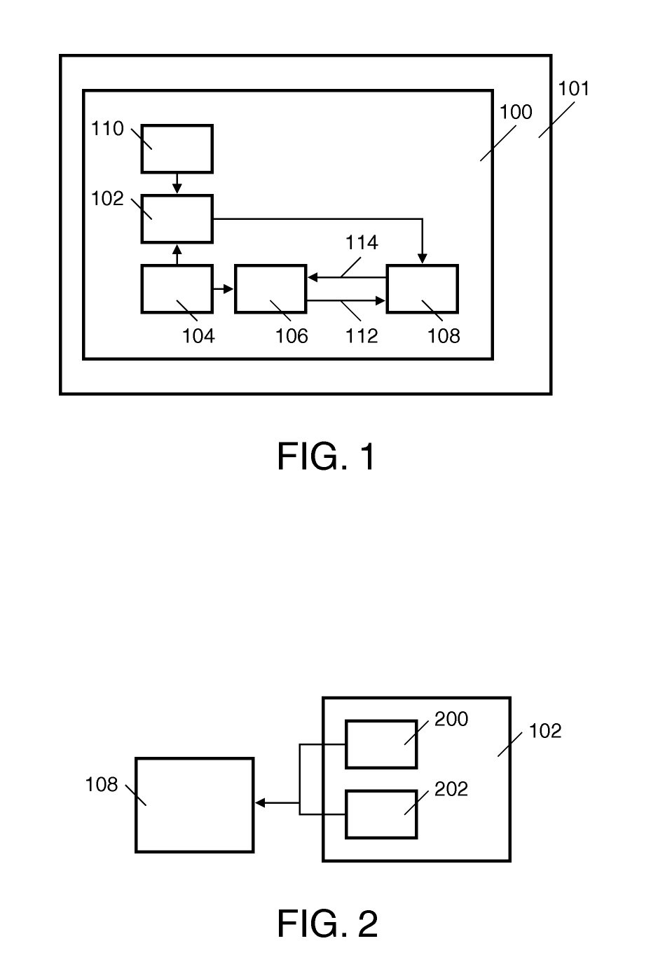

In FIG. 1 an embodiment of a data processing system 101 and a decoding system 100 is shown.

Data processing system 101 comprises decoding system 100. Decoding system 100 comprises an address generator 102, a controller 104, a decoder 106, a memory 108 and a reconfiguration means 110. Decoding system 100 is suitable for decoding a turbo code.

Decoder 106 is typically a SISO type decoder. Decoder 106 is connected to a memory 108, via connections 112 and 114. The connection 114 is used by decoder 106 for reading from memory 108 in response to an address. The connection 112 is used by decoder 106 for writing to memory 108. For ease of exposition the connection for writing and reading are indicated in FIG. 1 with separate reference signs, 112 and 114, although typically the connection from decoder 106 to memory 108 will be executed as a single connection, which single connection can be used both for reading and writing. For example, such a single connection may be executed as a bus.

Decoder 106 receives addresses from an address generator 102, for reading from memory 108. Controller 104 controls the address generator 102 and the decoder 106. Address generator 102 is reconfigurable using reconfiguration means 110.

During operation, the decoding system 100 receives a frame comprising data and redundancy, i.e. error correcting information. The frame is stored in memory 108. Decoder 106 corrects the errors that may be present in the frame, in a number of iterations. Each such iteration comprises a first half-iteration and a second half-iteration.

In a first half-iteration the decoder 106 reads data from memory 108 using connection 114. The reading is typically done sequentially and does not necessarily need addresses generated by address generator 102. Next, decoder 106 proceeds with correcting the data. When decoder 106 is finished with this correcting step, the corrected data produced by decoder 106 is written to memory 108 using connection 112. The writing is done sequentially and does not necessarily need addresses from address generator 102.

In a second half-iteration, the decoder 106 reads data from memory 108 using connection 114. The reading is done from interleaved addresses that are, at least partially, supplied by address generator 102. Next, decoder 106 proceeds with correcting the data. When decoder 106 is finished with this correcting step, the corrected data produced by decoder 106 is written to memory 108 using connection 112. The writing is done sequentially and does not necessarily need addresses from address generator 102.

Producing addresses and correcting data may be combined. For example, one or more addresses may be produced after which some progress on correcting is made, next one or more further addresses may be produced after which some further progress on correcting is made, and so on, until all addresses are produced and all correcting steps of a particular half-iteration are done.

Processing of a half-iteration is typically takes a number of clock cycles. In each clock cycle, the decoder 106 needs a new information item from memory 108 to work on. This is not necessary though; decoding system 100 may also work asynchronously, without using a clock.

In this way, reading using connection 114 is done sequentially in first half-iterations and according to addresses supplied by address generator 102 in second half-iterations. Note that alternatively, the roles of first and second half-iteration could be reversed, i.e. with the first half-iteration using interleaved addresses and the second half-iteration using linear addresses.

The number of iterations can be determined both statically and dynamically, using a so-called stopping rule. An overview of stopping rules is provided by “Stopping Rules for Turbo Decoders”; TMO progress report 42-142; Aug. 15, 2000; A. Matache, S. Dolinar and F. Pollara. For example, the stopping rule definitions from Section II may be used.

The reconfiguration means 110 and address generator 102 may be implemented according to any one of the further embodiments, discussed below.

In FIG. 2 an embodiment of address generator 102 is shown.

The address generator 102 comprises an interleaved address generator 200 and a linear address generator 202.

The decoding comprises a number of iterations. Each iteration comprises a first half-iteration and a second half-iteration.

In the first half-iteration the address generator 102 uses the linear address generator 202. Linear address generator 202 produces a linear sequence of addresses, e.g. a sequence of consecutive addresses. The SISO decoding is applied by decoder 106 on the information stored at the linear sequence of addresses in memory 108 in the order indicated by the linear sequence of addresses.

After the decoder 106 is finished, the decoded information is stored in memory 108 at the addresses indicated by the linear sequence.

Typically, the information stored in memory 108 on which decoder 106 acts, is called a-priori information. In the first half-iteration a-priori information is denoted as Ay1, in the second half-iteration as Ay2.

The information obtained when the decoder 106 has finished the first half-iteration is called Le1. The information obtained when the decoder 106 has finished the second half-iteration is called Le2.

Typically, Ay1, Ay2, Le1 and Le2 are expressed as log likelihood ratios. Such a log likelihood is typically around a byte in size. Log likelihoods of larger or smaller size are also possible.

In the second half-iteration the address generator 102 uses the interleaved address generator 200. Interleaved address generator 200 produces an interleaved sequence of addresses. The SISO decoding is applied by decoder 106 on the information stored at the interleaved sequence of addresses in memory 108 in the order indicated by the interleaved sequence of addresses. After decoder 106 is finished, the decoded information is stored in memory 108 at the addresses indicated by the interleaved sequence.

In this way, SISO decoding is applied to either linearly ordered or interleaved symbols. When a predefined number of iterations are reached or convergence is detected, the iterations are stopped and the output bits are obtained. The output bits typically are subject to further processing by data processing system 101. For example, the output bits may be forwarded to, e.g., an audio subsystem and be subjected to audio processing.

It can be seen that Ay1 is a reordering, i.e. a permutation, of Le2. Likewise, Ay2 is a reordering of Le1. The decoder 106 may also use so-called extrinsic information.

In this embodiment, the interleaver is a linear interleaver. This class of interleavers is used in standards, such as the UMTS LTE, WiMax and WiBro standards. A linear interleaver is specified by a polynomial expression, as is shown in polynomial 404 in FIG. 4.

Not all choices for the coefficients of the polynomial give a conflict free interleaver. However, many such choices exist and are known in the art. This embodiment provides for a conflict-free linear interleaver for use in a turbo decoding system 100.

To generate a list of interleaved addresses, interleaved address generator 200 evaluates the polynomial 404 successively in each of the values 0 up to k−1. The generated list comprises the interleaved addresses on which decoder 106 is to act during an interleaved half-iteration. The generated list is also given in formula 402 in FIG. 4.

Before the addresses generated by address generator 102 are forwarded to memory 108, a memory mapping step may take place, e.g., by a memory manager (not shown).

Choosing a different block size for use in the address generator 102 is not regarded as reconfiguring the address generator 102. Rather, the term ‘reconfiguring’ means adapting the address generator 102 to use a different interleaving scheme. For example, if the interleaving scheme is based on a polynomial, then a reconfiguration can be done by reconfiguring the polynomial. A new block size could be achieved by merely running the polynomial longer and adapting the modulus; a new block size does not necessitate reconfiguring the interleaving scheme itself.

As different types of turbo decoding are used in different standards, it is desirable to have an architecture that can support more than one type of turbo code. One of the challenges of a multi-standard turbo decoder lies in finding an interleaver, i.e. address generator 102 that can handle more than one interleaving scheme.

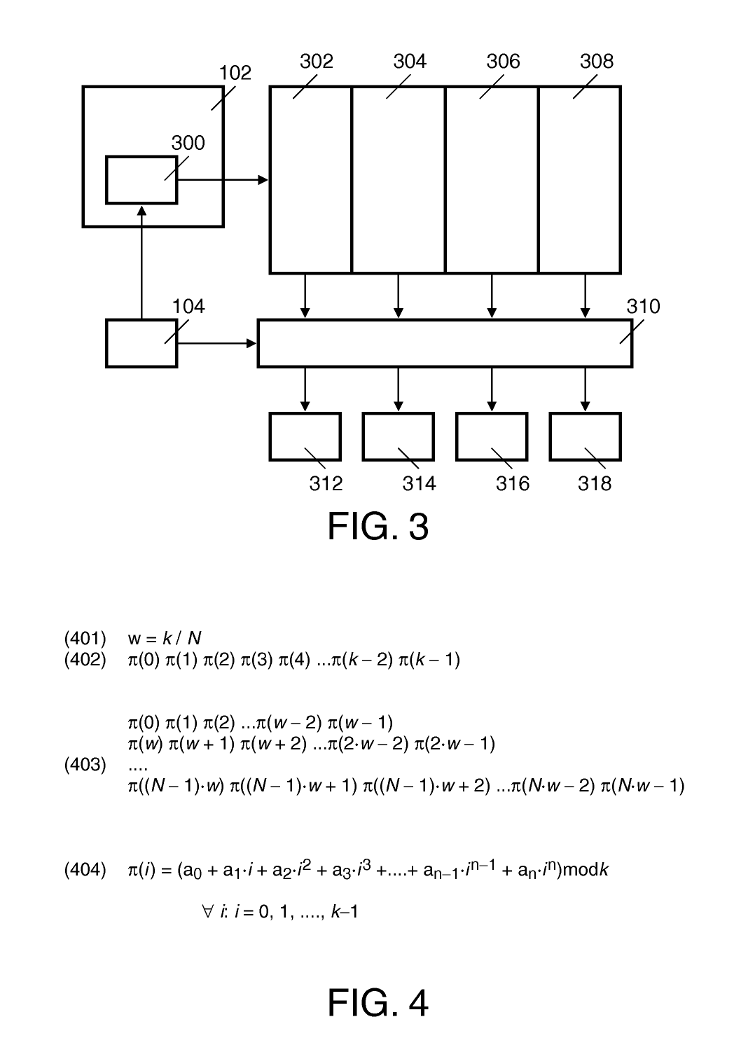

In FIG. 3 an embodiment of turbo decoding system 100 is shown.

The address generator 102 comprises a basic sequence generator 300. The decoding system 100 comprises four memory banks 302, 304, 306 and 308. Each memory bank is connected to a network 310. The network 310 is connected to four decoders 312, 314, 316 and 318. Decoders 312-318 are typically SISO decoders.

This embodiment of turbo decoding system 100 is capable of working with multiple decoders in parallel. Let N be the number of decoders. FIG. 3 shows the number of decoders as four. This number is, however, an example, and does not limit the invention.

In parallel turbo decoders, multiple decoders, e.g., SISO blocks, are used instead of one single decoder 106. These decoders work on one frame, and need access to the extrinsic information at the same time. When accessing the memory in a linear fashion, this can be done by dividing the frame into ‘chunks’ in a linear fashion. However, this cannot always be done for interleaved access.

When an ordinary turbo decoding scheme is parallelized it may happen, because of the interleaving, that two decoders need access to the same memory bank, at the same time. Such a situation is called a ‘conflict’.

To enable interleaved parallel access, it is preferred that a conflict-free interleaver is used. A conflict-free interleaver allows the sequence of addresses to be split up in multiple chunks, such that each chunk only needs access to a single memory bank. In this embodiment, the interleaver is a linear interleaver. This class of interleavers can be designed to be conflict-free.

With N decoders, a parallel interleaver generates N addresses in each clock cycle. Each address corresponds to a ‘chunk’ of the total block. Such a chunk is named ‘sub-sequence’. Each sub-sequence has ‘w’ elements, where ‘w’ is called the sub-sequence length. Let k be the block size of the turbo code in use. Typically, k is the length of a received frame. Then, w can be computed as indicated in formula 401 in FIG. 4.

The entire interleaver sequence is indicated in formula 402 in FIG. 4. The parallel interleaver has to generate in parallel the sub-sequences indicated in formula 403 in FIG. 4.

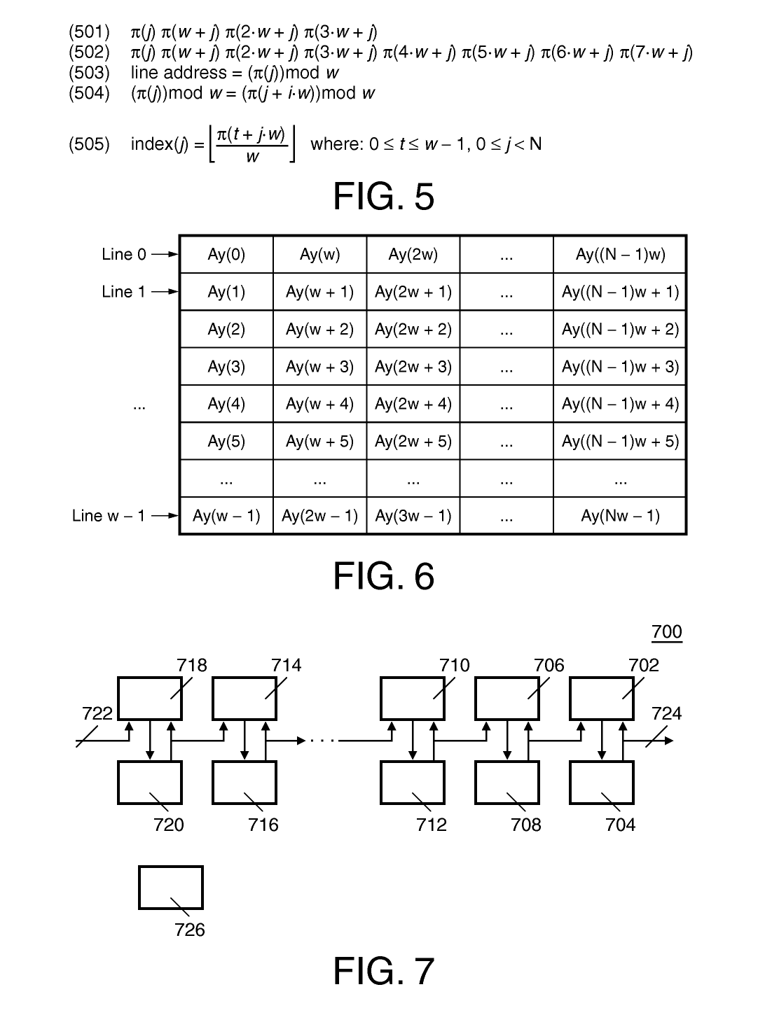

For example, if four decoders are used, i.e. N=4, at time j, the elements that are retrieved from memory are indicated with the reference numeral 501 in FIG. 5. For example, if eight decoders are used, i.e. N=8, the elements that have to be accessed at the time j are indicated with reference numeral 502 in FIG. 5.

Note that, although going from 4 to 8 decoders will in general be allowed by the turbo code, the interleaving scheme will not necessarily remain conflict free.

Once the data is retrieved from the memory, it needs to be shuffled, i.e. permutated, so that each SISO gets the data word it requires. The controller 104 prepares the required shuffle pattern for the shuffle and the network 310 shuffles the read memory line in order to present the right element to each SISO block. Below, the functions and the interaction of these blocks will be explained. By reconfiguring, for example through reconfiguration registers, the same architecture can be used for multiple standards, for example, both UMTS LTE and WiMax.

In a more advanced embodiment the basic sequence generator 300 only computes a single address in each clock cycle, i.e. the line address, and sends the line address to each of the memory banks 302-308. Each of the memory banks 302-308 retrieve an information item from the memory line indicated by the line address. The basic sequence generator 300 and interleaving scheme are configured such that the collection of data collectively retrieved from the memory banks 302-308 is the set of data needed by decoders 312-318 in that iteration at that moment.

Typically, there will be some mapping of memory after the basic sequence generator 300 has computed the memory lines. For example, a memory manager (not shown) may map computed memory lines to physical addresses. Decoders 312-318 typically process their input data sequentially using a, so-called, trellis to decode a convolutional code. In a memory line in a memory bank there is a data word, i.e. one information item, e.g. one log likelihood, in Ay1 or Ay2.

The line address is defined as in formula 503 in FIG. 5. The line address has the property shown in equation 504. This follows because the modulo operation acts as a homomorphism for addition and multiplication.

It follows from the above that all the elements that are needed at time j have the same line address. Now consider the memory mapping of the data words for the interleaver as shown in FIG. 6. The data is stored in the memory in a column-wise fashion such that each memory line includes exactly one word from each sub-sequence. The columns in FIG. 6 correspond to the memory banks 302-308 in FIG. 3.

When a line is accessed by multiple decoders, the elements of this line have to be shuffled in order to give each SISO the correct element. This is the role of network 310. An element that has to be given to the j-th decoder at instant t, has an index within the memory line. The index within the memory line is computed as indicated by formula 505 in FIG. 5.

In operation, the basic sequence generator 300 generates a subsequence of the address sequence used by the interleaved address generator 200, modulo w. This subsequence is also called the ‘basic sequence’. The basic sequence is appropriate for the half-iteration that uses the interleaved addresses. Upon receiving an address from the basic sequence generator 300, a memory bank retrieves multiple information items. The multiple information items are sent to a network 310, which performs a permutation on the multiple information items.

After the permutation the four decoders work in parallel to decode their part of the frame.

If the memory is configured such that a single line can be read with a single read operation, then the memory banks 302-308 can be implemented as a single memory. In this case the basic sequence generator 300 needs only to send the line address a single time.

In FIG. 7 an embodiment of a polynomial evaluator is shown.

A polynomial evaluator can be used for the embodiments of FIGS. 1 and 2 as well as for the parallel embodiment of FIG. 3. In the parallel embodiment the polynomial evaluator is used to produce the basic sequence. In the embodiments of FIGS. 1 and 2, the polynomial evaluator is used to produce the interleaved sequence itself.

Polynomial evaluator 700 comprises a plurality of adders, shown are the adders 702, 706, 710, 714 and 718. Polynomial evaluator 700 also comprises a plurality of buffers, shown are buffers 704, 708, 712, 716 and 720. A specific buffer is associated with each specific adder. Adders 702, 706, 710, 714 and 718 are associated with buffers 704, 708, 712, 716 and 720, respectively.

Note that, although FIG. 7 shows 5 adders, this number is in no way special. Polynomials of different degrees can be expressed with a different number of adders. Both a smaller number and a larger number than 5 are possible, for the number of adders.

The plurality of adders is ordered linearly, and the plurality of adders comprises a first adder, e.g. 718, and a last adder, e.g. 702. This means that before each adder, except the first adder, there is a previous adder and after each adder except the last adder there is a next adder.

Each specific adder takes as input the contents of its associated buffer. Each specific adder, except the first adder, also takes as input the contents of the buffer associated with a specific previous adder.

First adder 718 takes as input the contents of its associated buffer 720 and a constant number which is put on input 722. The output of adder 718 is stored in buffer 720.

Adder 714 is the next adder after adder 718. Adder 714 takes as input the content of its associated buffer 716 and the content of the buffer 720 associated with the previous adder 718. Note the content of buffer 720 is used by adder 714 before the result of adder 718 is stored in buffer 720.

A number of adders can follow adder 714, using the same pattern.

Last adder 702 takes as input the content of buffer 708 and the content of buffer 704. The result of adder 702 is stored in buffer 704 but is also the final output of this iteration of the polynomial evaluator. The final output appears on output 724. The output can then be used as generated address, or generated line address.

Before the polynomial evaluations start, a configuration unit 726 stores in each specific one of the buffers 704, 708, 712, 716 and 720 a specific parameter representative of the polynomial to be evaluated. Note that the parameters need to be specially chosen such that the polynomial evaluator 700 gives the correct results.

During operation, at the start of an interleaved half-iteration, the configuration unit 726 fills the buffers 704, 708, 712, 716 and 720 with start values. Also on input 722 a further starting value is placed. All the adders add their inputs modulo a modulus, i.e. a further value. In case the polynomial evaluator is used for an interleaver as in FIG. 1 or 2, the adders work modulo k, i.e. the block size of the turbo code. If the polynomial evaluator is used to compute a basic sequence as in the embodiment of FIG. 3, the adders work modulo w, i.e. the size of the subsequences.

After all adders have functioned once, all the buffers receive a new value from their associated adders, which they store. In the next iteration, the next value of the polynomial is computed. The buffers are not configured again by configuration unit 726. However, on input 722 the same number is used as in the previous iteration. For a fixed polynomial the input 722 remains constant throughout the iteration, whereas the buffers are periodically updated. After all adders have again functioned once, and all buffers are updated once, a new value is produced at output 724. In this manner the polynomial evaluator is iterated until all necessary values have been produced in sequence.

To prepare the polynomial evaluator for the next interleaved half-iteration of the turbo decoding in which it is to be used, the buffers need to be reset again to their initial values by the configuration unit 726.

The adders typically execute a modular addition. Such a modular addition may be done in several ways. Preferably, the modular addition is done as a differential modulo operation. A differential modulo operation is defined for inputs ‘a’ and ‘b’ and modulus ‘c’. The ‘a’ and ‘b’ are required to be greater than or equal to 0 and smaller than ‘c’. The value of ‘(a+b) mod c’ can be computed by first adding ‘a’ and ‘b’ using ordinary arithmetic and second subtracting ‘c’ in case the addition gave a result larger than ‘c’. In this case the modular addition only requires at most one ordinary addition, one comparison and one subtraction. In our example above ‘c’ is either k or w.

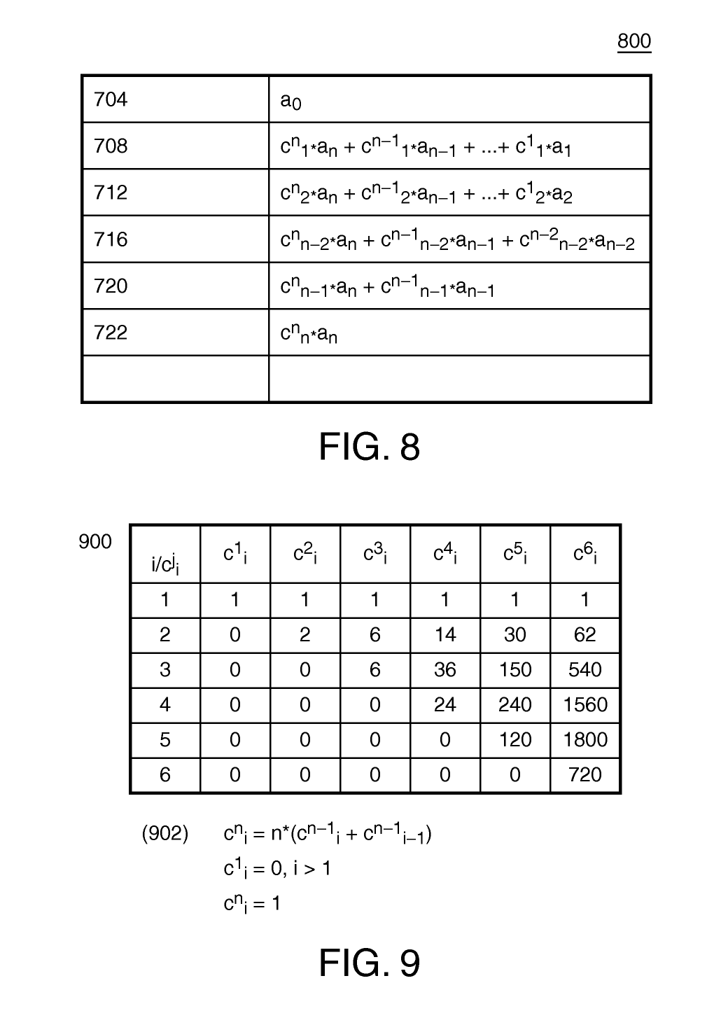

FIG. 8 shows table 800. Table 800 gives formulas to compute the parameters that are to be placed by the configuration unit 726 in the buffer 704, 708, 712, 716 and 720. Table 800 also gives the number that is to be placed on input 722. Each parameter is expressed as a sum involving the coefficients of the polynomial 404 and coefficients that are independent of the polynomial. The values of the latter coefficients, indicated with the letter ‘c’ are indicated in table 900 in FIG. 9. Note that the recurrence relations 902 allow to compute further values of table 900 should larger polynomials be desired.

Given a particular polynomial of a particular degree, Table 800 gives the parameters needed to configure polynomial evaluator 700 for evaluation of the particular polynomial. Table 800 uses coefficients ‘c’, whose values are given in Table 900. The number of columns needed from Table 900, counting from the left, is equal to the particular degree. The rows of the table indicate the register values where the table constants are used to calculate.

For example, for a polynomial of degree 2, rows 1 and 2 are needed and the table contents up to column 2 are used. Row 1 would be used for buffer 704. Column 2 would be used for buffer 708.

The index of the ‘c’ indicated as a superscript corresponds to a particular buffer. Superscripted indices 1, 2, . . . correspond to buffers 708, 712, . . . , respectively. The index of ‘c’ indicated with a subscript is used to add the appropriate coefficients for a certain buffer. Collectively, Table 800 and Table 900 give an algorithm for computing the start values that need to be placed in buffers 708-720, given a particular polynomial.

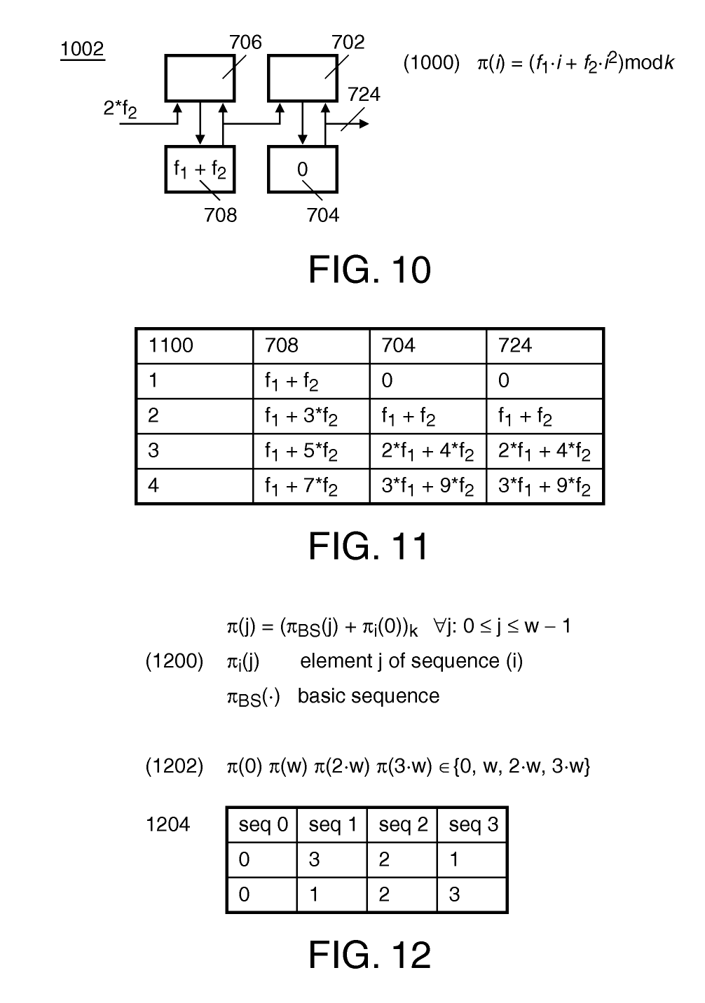

In FIG. 10 an embodiment of a polynomial evaluator 1002 is shown.

A particular class of linear interleavers is based on quadratic permutation polynomials (QPP). A quadratic permutation polynomial is a polynomial of degree two that can be described with two parameters, as shown in FIG. 10, formula 1000. The QPP should have the property that the polynomial describes a permutation. Not all choices for the parameters give rise to a quadratic permutation polynomial. Some possible choices for f₁, f₂ and the modulus are described in: WWRF/WG4/Subgroup on Channel Coding, Editors: Thierry Lestable and Moshe Ran, Error Control Coding Options for Next Generation Wireless Systems, Section 2.3.2.1.1 ‘Maximum Contention-Free Permutation Polynomials Interleavers’.

By taking for the parameters appropriate choices, and also adapting the modulus used in the adders, and the input 722, the polynomial evaluator 1002, shown in FIG. 10, can be made to use any linear interleaver based on a quadratic permutation polynomial 1000. The cited document above shows that this type of interleaver has superior frame error rates. The ability to support all quadratic permutation polynomials 1000 is therefore of great advantage.

The reconfiguration can be conveniently done via configuration unit 726. For example, by configuring the configuration unit 726 to access a different list of parameters, the configuration unit 726 will then update from this different list of parameters.

In polynomial evaluator 1002, the initial values that are to be placed in the buffers 704 and 708 at the start of an interleaved half-iteration are shown in the buffers. Note that after the first iteration, the values in the buffers will be different, although one value on the input to adder 706 remains constant.

In FIG. 11 the first few values of the buffers 708, 704 and output 724 are shown, for the interleaver of FIG. 10. The column indicated with reference numeral 1100 indicates the clock cycle during which the shown buffers assume the indicated values.

If the interleaver of FIG. 10 is used in the architecture of FIG. 3, a suitable choice for the network 310 is presented.

If four decoders are used, i.e. N=4, four sub-sequences have to be generated. The coefficients have been chosen in order to have the property given in formula 1200 in FIG. 12.

It is possible to compute each particular sub-sequence using the first sub-sequence, i.e. the basic sequence, and adding the first element of the particular sub-sequence. The first element of each sub-sequence is a multiple of the sub-sequence length, w, as in formula 1202, in FIG. 12.

There are only two possible patterns which identify the first element of each sub-sequence. Table 1204 in FIG. 12 can be used, where a number ‘x’ means that the first element of the corresponding sub-sequence is x·w.

For each block size, one of the two rows has to be identified; this pattern is called the initial pattern. This information will be used by the controller 104 to identify the way in which the elements have to be shuffled before becoming the inputs of the SISO blocks. The controller 104 sends the appropriate initial pattern, as taken from table 1204, and sends the initial pattern to network 310. Network 310 uses the pattern to shuffle the information retrieved from memory banks 302-308.

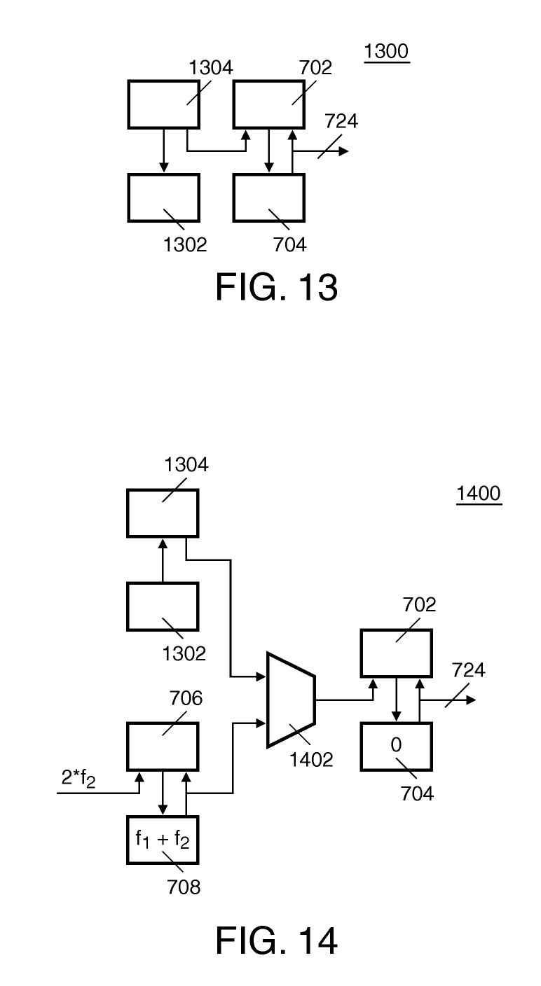

FIG. 13 shows a further embodiment of a polynomial evaluator 1300 for use in an address generator 102, in particular for use in an address generator based on a polynomial, such as, for example, generator 200 or 300 might be.

Similar to polynomial evaluator 700, the polynomial evaluator 1300 comprises a plurality of adders and a plurality of buffers, connected in the same way as in polynomial evaluator 700.

Polynomial evaluator 1300 however comprises a further memory 1304 and a counter 1302. The further memory 1304 stores a plurality of numbers. The counter may be periodically processed, for example, the counter may be reduced modulo 4.

The further memory 1304 is configured to retrieve one of the plurality of numbers under the control of a counter 1302. Typically, counter 1302 is a cyclic counter.

For each new data word, the turbo decoding system 100 increments the counter 1302.

The retrieved number is used as an additional input for the last adder 702. In the embodiment shown in FIG. 13, which is with only one adder, the adder 702 has two inputs. In an embodiment of the polynomial evaluator with more than one adder, the last adder will have at least three inputs.

Polynomial evaluator 1300 can be reconfigured by changing the initial value of the plurality of buffers, including buffer 704, and changing the contents of further memory 1304.

The architecture of FIG. 13 is particularly useful for the WiMax standard. The result of the further memory 1304 is that for some values of the input of the polynomial a different constant term is used. This broadens the number of permutations, i.e. interleaving schemes that can be used with the polynomial evaluator, compared to those permutations that can be expressed strictly with only a polynomial.

FIG. 14 shows a further embodiment of a polynomial evaluator 1400 for use in an address generator 102.

The polynomial evaluator 1400 combines polynomial evaluator 1300 and polynomial evaluator 1002.

Polynomial evaluator 1400 comprises a multiplexer 1402. The multiplexer 1402 receives input from a buffer 708 and from a further memory 1304. By selecting the multiplexer 1402 to use the input from the further memory 1304, the embodiment can be configured for interleaving schemes that use polynomial evaluator 1300. By selecting the multiplexer 1402 to use the content of buffer 708 as an input, polynomial evaluator 1400 can be used for interleaving schemes that use polynomial evaluator 1002.

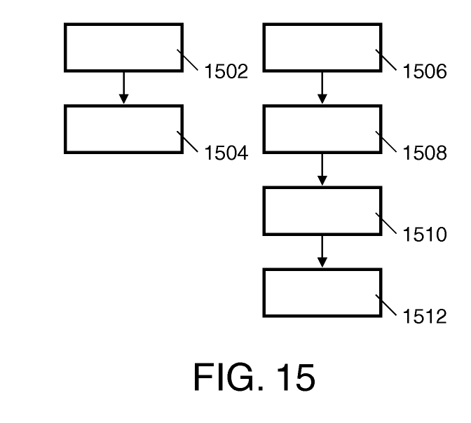

FIG. 15 is a flowchart representing a method of reconfiguring a turbo decoding method.

Step 1502 of the method of reconfiguring, the method receives reconfiguration information. In step 1504 the method reconfigures an interleaving scheme in dependency on the reconfiguration information. Note that step 1504 can be done while the turbo decoding system 100 is in operational use.

The turbo decoding method comprises the step of 1506: producing a sequence of addresses according to the interleaving scheme; the step 1508: retrieving a first information from a memory as indicated by the sequence of addresses; the step 1510: producing a second information by performing a turbo decoding half-iteration on the retrieved first information; and the step 1512: storing the second information as indicated by the sequence of addresses.

The order of the steps can be varied or some steps may be executed in parallel, as will be apparent to a person skilled in the art. For example, steps 1506, 1508 and 1510 may be executed, at least partially, in parallel. Moreover, it is not the case that one step needs to be completely finished before some other step is started. After part of the sequence of addresses is produced, a part of the information will be retrieved. After part of the information is retrieved the decoding will commence.

The present invention, as described in embodiments herein, may be implemented using a programmed processor executing programming instructions that are broadly described above in flow chart form that can be stored on any suitable electronic storage medium. However, those skilled in the art will appreciate that the processes described above can be implemented in any number of variations and in many suitable programming languages without departing from the present invention. For example, the order of certain operations carried out can often be varied, additional operations can be added or operations can be deleted without departing from the invention. Error trapping, enhancements and variations can be added without departing from the present invention. Such variations are contemplated and considered equivalent.

The present invention could be implemented using special purpose hardware and/or dedicated processors. Similarly, general purpose computers, microprocessor based computers, digital signal processors, microcontrollers, dedicated processors, custom circuits, Application Specific Integrated Circuits (ASICs) and/or dedicated hard wired logic may be used to construct alternative equivalent embodiments of the present invention. In a claim enumerating several means, several of these means may be embodied by one and the same item of hardware.

Those skilled in the art will appreciate that the program steps and associated data used to implement the embodiments described above can be implemented using disc storage as well as other forms of storage, such as, for example, Read Only Memory (ROM) devices, Random Access Memory (RAM) devices, optical storage elements, magnetic storage elements, magneto-optical storage elements, flash memory and/or other equivalent storage technologies without departing from the present invention. Such alternative storage devices should be considered equivalents.

While the invention has been described in conjunction with specific embodiments, it is evident that many alternatives, modifications, permutations and variations will become apparent to those of ordinary skill in the art in light of the foregoing description. Accordingly, it is intended that the present invention embrace all such alternatives, modifications and variations as fall within the scope of the appended claims.

1. A data processing system comprising:
a turbo decoding system including a plurality of electronic circuits, the electronic circuits including a memory, an address generator, and a Soft Input Soft Output decoder, wherein:
the memory is operative to store a first information;
the address generator is operative to produce a sequence of addresses according to an interleaving scheme;
the memory is operative to retrieve the first information as indicated by the sequence of addresses;
the Soft Input Soft Output decoder is operative to produce a second information by performing a turbo decoding half-iteration on the retrieved first information;
the memory is operative to store the second information as indicated by the sequence of addresses;
the address generator is operative to receive reconfiguration information; and
the address generator is operative to reconfigure during operational use the interleaving scheme in dependency on the reconfiguration information.

2. A data processing system as in claim 1, wherein:
the interleaving scheme is based on a polynomial;
the address generator includes a polynomial evaluator, the polynomial evaluator is operative to produce a polynomial evaluation;
the polynomial evaluator includes a first plurality of parameters representative of the polynomial; and
the reconfiguration information includes at least one second plurality of parameters representative of a reconfigured polynomial.

3. A data processing system as in claim 2, wherein
the polynomial evaluator includes:
a third plurality of adders, a fourth plurality of buffers and a configuration unit;
the third plurality of adders is ordered linearly, the third plurality of adders includes a first adder and a last adder;
to each specific one of the third plurality of adders is associated a specific one of the fourth plurality of buffers;
each specific one of the third plurality of adders is configured to produce a specific output by adding, modulo a first number, a specific fifth plurality of inputs, the specific fifth plurality of inputs includes a contents of the specific buffer associated with the specific adder; the specific adder is configured to store the specific output in the specific buffer;
the specific fifth plurality of inputs to each specific one of the third plurality of adders, except the first adder, includes a contents of a specific previous buffer associated with a specific previous adder;
the last adder produces a last output, which last output is representative of the polynomial evaluation; and
the configuration unit is operative to store in each specific one of the fourth plurality of buffers a specific one of the first plurality of parameters representative of one of the polynomial and the second plurality of parameters representative of the reconfigured polynomial.

4. A data processing system as in claim 3, wherein the address generator comprises a further memory and a counter; wherein:
the further memory is operative to store a seventh plurality of numbers;
the turbo decoding system is operative to increment the counter in conjunction with the Soft Input Soft Output decoder performing the turbo decoding half-iteration;
the further memory is operative to retrieve a specific one of the seventh plurality of numbers in dependency on the counter;
the last adder is operative to receive as input an eighth plurality of inputs, the eighth plurality of inputs includes the specific number.

5. A data processing system as in claim 3, wherein the address generator comprises a further memory and a counter; wherein:
the further memory is operative to store a seventh plurality of numbers;
the turbo decoding system is operative to increment the counter in conjunction with the Soft Input Soft Output decoder performing the turbo decoding half-iteration;
the further memory is operative to retrieve a specific one of the seventh plurality of numbers in dependency on the counter;
a particular one of the third plurality of adders is configured to receive an input from a particular previous adder and the specific number;
the particular adder is operative to select one of the input from the particular previous adder and the specific number, for use in the adding.

6. A mobile communication device including the data processing system as in claim 1.

7. A turbo decoding system for use in a data processing system as in claim 1.

8. An address generator for use in a data processing system as in claim 1.

9. A method of reconfiguring a turbo decoding method, including:
receiving reconfiguration information; and
reconfiguring during operational use of the turbo decoding method an interleaving scheme in dependency on the reconfiguration information;
the turbo decoding method comprising:
producing a sequence of addresses according to the interleaving scheme;
retrieving a first information from a memory as indicated by the sequence of addresses;
producing a second information by performing a turbo decoding half-iteration on the retrieved first information; and
storing the second information as indicated by the sequence of addresses.

10. A computer program product comprising computer code for implementing the method as defined in claim 9.
